(19) United States
(12) Patent Application Publication
(10) Pub. No.: US 2005/0036052 A1
(43) Pub. Date: Feb. 17, 2005

(54) Solid-state image pickup device and manufacturing method thereof

(75) Inventors: Katsunori Kokubun, Kanagawa (JP); Mitsuru Sato, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: Sony Corporation

(21) Appl. No.: 10/895,595

(22) Filed: Jul. 21, 2004

(30) Foreign Application Priority Data
Aug. 11, 2003 (JP) P2003-291726

(51) Int. Cl. H04N 5/335

(52) U.S. Cl. 348/311

(57) ABSTRACT

A solid-state image pickup device is constructed in which a charge transfer portion is provided on one side of a light-receiving sensor portion, the charge transfer portion is composed of charge transfer electrodes 2A, 2B of a plurality of layers, sidewall insulating layers 11, 8 being formed on the side surfaces of the charge transfer electrodes 2A, 2B of the respective layers of the charge transfer electrodes of a plurality of layers. A method of forming the above-described solid-state image pickup device manufacturing method comprises the process for forming the charge transfer electrodes 2A, 2B and the process for forming an insulating film on the whole surface and forming the sidewall insulating layers 11, 8 on the side surfaces of the charge transfer electrodes 2A, 2B of the respective layers by effecting etch-back process on this insulating film. It is possible to provide the solid-state image pickup device having the structure in which the charge transfer electrode can be suppressed from being reduced in size due to oxidation caused when the interlayer insulators are formed on the charge transfer electrodes and in which the number of the pixels of the solid-state image pickup device can be increased and the solid-state image pickup device can be increased in density and a manufacturing method of such solid-state image pickup device.

### BACKGROUND OF THE INVENTION

1. Field of the Invention

The present invention relates to a solid-state image pickup device and a manufacturing method thereof.

2. Description of the Related Art

A charge-coupled device type solid-state image pickup device, that is, a CCD (charge-coupled device) solid-state image pickup device is a functional device having function to transfer accumulated electrons as well as function to accumulate photo-electrically converted electrons and is employed as an image pickup device, a delay device and the like.

A CCD solid-state image pickup device comprises a transfer register portion having a CCD structure provided as a charge transfer portion and light-receiving sensor portions composed of photodiodes for photoelectrically-converting and accumulating signal charges, the thus photoelectrically-converted signal charges being accumulated being read out from the light-receiving sensor portions to the transfer register and the signal charges being transferred in the transfer register.

The transfer register comprises charge transfer electrodes formed through insulating layers on transfer channel through which signal charges are transferred. Voltage pulses with phases different from each other should be applied to adjacent charge transfer electrodes in order to transfer signal charges, and the channels should be prevented from being disconnected. To this end, the charge transfer electrode is composed of two electrode layers of first and second layers and the end portion of the charge transfer electrode of the second layer slightly overlaps the charge transfer electrode of the first layer (see cited patent reference 1, for example).

FIG. 1 is a schematic diagram (that is, plan view of a main portion) of an arrangement of an example of a CCD solid-state image pickup device according to the related art.

A CCD solid-state image pickup device, generally depicted by the reference numeral 1 in FIG. 1, comprises light-receiving sensor portion 51 arrayed in a matrix fashion (that is, in a two-dimensional fashion) and vertical transfer registers 53 provided on the left-hand sides of the columns of the light receiving sensor portion 51. This vertical transfer register 53 includes the substrate in which a vertical transfer channel is formed, although not shown, a charge transfer electrode 52 being formed on an insulating film. The charge transfer electrode 52 is composed of a charge transfer electrode 52A of a first layer and a charge transfer electrode 52B of a second layer and the charge transfer electrode 52A of the first layer and the charge transfer electrode 52B of the second layer are formed so as to partly overlap with each other.

The charge transfer electrode 52 (52A, 52B) is an electrode made of a material such as a poly-crystalline silicon, a high melting-point metal and a material made of both a poly-crystalline silicon and a high melting-point metal.

In the case of the structure shown in FIG. 1, respective layers of the charge transfer electrode 52A of the first layer and the charge transfer electrode 52B of the second layer and a light-shielding film, not shown, should be insulated from each other by insulating films in order to maintain a withstand voltage.

The insulating film between the two layers is deposited by direct oxidation of the charge transfer electrode or both of direct oxidation of the charge transfer electrode and deposition of the insulating film.

[Cited Patent Reference 1]:
Official Gazette of Japanese laid-open patent application No. 9-312390

However, as CCD solid-state image pickup devices become more microminiaturized progressively, the structure of the charge transfer electrode and the manufacturing method according to the related art encounter with the following problems inevitably.

For example, when the CCD solid-state image pickup device 50 shown in FIG. 1 is manufactured, in the process for forming an oxide film used to insulate the charge transfer electrode 52A of the first layer and the charge transfer electrode 52B of the second layer from each other and in the process for forming an interlayer insulator used to insulate the charge transfer electrode 52B of the second layer and the light-shielding layer, it is unavoidable that the charge transfer electrodes 52A, 52B are oxidized at their portions near the surfaces as the above-mentioned electrodes 52A, 52B are directly oxidized.

When the CCD solid-state image pickup device becomes microminiaturized progressively, the size of the charge transfer electrode also is reduced but the thickness of the oxidized portion is not so changed considerably. As a result, the ratio of the oxidized portion increases and hence the ratio in which the electrode is reduced by oxidation becomes remarkable.

Since the charge transfer electrode is reduced in size as described above, a low sheet resistance cannot be obtained in the charge transfer electrode, for example, and a problem arises, in which charge transfer efficiency is deteriorated by propagation delay.

In particular, in the charge transfer electrode which is applied with a read voltage for reading signal charges, that is, a read electrode (the charge transfer electrode 52B of the second layer, for example, in the CCD solid-state image pickup device shown in FIG. 1), when the charge transfer electrode is reduced in size, the charge transfer electrode is disconnected from the gate insulating film and thereby a distance between the semiconductor region beneath the gate insulating film and the electrode increases. There then arises a problem, in which the read voltage necessary for reading the signal charges rises unavoidably.

Since the solid-state image pickup device should be microminiaturized more as the number of pixels of the solid-state image pickup device increases considerably and the solid-state image pickup device becomes higher in density, the above-mentioned problems will become more serious.

In order to increase the number of the pixels of the solid-state image pickup device and in order to make the solid-state image pickup device become higher in density, it is necessary to suppress the charge transfer electrode from being reduced in size due to oxidation required when the interlayer insulator is formed on the charge transfer electrode.

### SUMMARY OF THE INVENTION

In view of the aforesaid aspect, it is an object of the present invention to provide a solid-state image pickup device in which a charge transfer electrode can be suppressed from being reduced in size due to oxidation required when interlayer insulators are formed on the charge transfer electrode, the number of pixels in the solid-state image pickup device can be increased and in which the solid-state image pickup device can be increased in density and a manufacturing method of such solid-state image pickup device.

In the solid-state image pickup device according to the present invention, the charge transfer portion is provided on one side of the light-receiving sensor portion, the charge transfer portion is composed of charge transfer electrodes of a plurality of layers, and sidewall insulating layers are formed on side surfaces of the charge transfer electrodes of the respective layers of the charge transfer electrodes of a plurality of layers.

According to the arrangement of the above-mentioned solid-state image pickup device of the present invention, since the charge transfer portion is composed of the charge transfer electrodes of a plurality of layers and the sidewall insulating layers are respectively formed on side surfaces of the charge transfer electrodes of the respective layers of the charge transfer electrodes of a plurality of layers, in the process for forming the interlayer insulators over the charge transfer electrodes of the respective layers when the solid-state image pickup device is manufactured, it becomes possible to make the side surfaces of the charge transfer electrodes become difficult to be oxidized by the sidewall insulating layers. As a result, it becomes possible to suppress the charge transfer electrodes from being reduced in size due to the oxidation.

A solid-state image pickup device manufacturing method according to the present invention is the method for forming the solid-state image pickup device in which the charge transfer portion is provided on one side of the light-receiving sensor portion, the charge transfer portion being composed of the charge transfer electrodes of a plurality of layers. This solid-state image pickup device manufacturing method comprises the process for forming the charge transfer electrodes and the process for forming the sidewall insulating layers on the side surfaces of the charge transfer electrodes of the respective layers of the charge transfer electrodes of a plurality of layers by effecting etch-back process on this insulating film.

According to the above-mentioned solid-state image pickup device manufacturing method of the present invention, this manufacturing method includes the process for forming the charge transfer electrodes and the process for forming the sidewall insulating layers on the side surfaces of the charge transfer electrodes of the respective layers of the charge transfer electrodes of a plurality of layers by effecting the etch-back process on this insulating film, the side surfaces of the charge transfer electrodes can be made difficult to be oxidized by forming the sidewall insulating layers on the side surfaces of the charge transfer electrode. As a result, it is possible to suppress the charge transfer electrode from being reduced in size due to the oxidation.

In the solid-state image pickup device according to the present invention, the charge transfer portion is provided on one side of the light-receiving sensor portion, the charge transfer portion is composed of the charge transfer electrodes of a plurality of layers and the sidewall insulating layers are formed on the side surfaces of at least the read electrodes of the charge transfer electrodes of a plurality of layers.

According to the arrangement of the above-mentioned solid-state image pickup device of the present invention, since the charge transfer portion is composed of the charge transfer electrodes of a plurality of layers and the sidewall insulating layers are formed on the side surfaces of the read electrode of the charge transfer electrodes of a plurality of layers, in the process for forming the interlayer insulators over the read electrode when the solid-state image pickup device is manufactured, it becomes possible to make the side surfaces of the read electrode become difficult to be oxidized by the sidewall insulating layers. As a consequence, it becomes possible to suppress the read electrode from being reduced in size due to the oxidation.

A solid-state image pickup device manufacturing method of the present invention is a method of manufacturing a solid-state image pickup device in which a charge transfer portion is formed on one side of a light-receiving sensor portion and in which the charge transfer portion is composed of charge transfer electrodes of a plurality of layers. This solid-state image pickup device manufacturing method comprises the process for forming the charge transfer electrodes and the process for forming an insulating film on the whole surface and for forming sidewall insulating layers on the side surface of at least a read electrode of the charge transfer electrodes of a plurality of layers by effecting etch-back process on this insulating film.

According to the above-mentioned solid-state image pickup device of the present invention, since this solid-state image pickup device manufacturing method comprises the process for forming the charge transfer electrodes and the process for forming the insulating film on the whole surface and for forming the sidewall insulating layers on the side surfaces of at least the read electrode of the charge transfer electrodes of a plurality of layers, respectively, it is possible to make the side surfaces of the read electrode become difficult to be oxidized by forming the sidewall insulating layers on the side surfaces of the read electrode. As a result, it is possible to suppress the read electrode from being reduced in size due to the oxidation.

According to the present invention, since the sidewall insulating layers are formed in the side surfaces of the charge transfer electrodes of the respective layers, when the interlayer insulators are formed on the charge transfer electrodes, it is possible to suppress the electrodes from being reduced in size due to the oxidation by suppressing the oxidation of the charge transfer electrodes.

Thus, by suppressing the resistance from being increased as the charge transfer electrodes are reduced in size, it is possible to solve the problem of the propagation delay in the charge transfer electrode. Also, it is possible to solve the problem in which the charge transfer efficiency is deteriorated by the reduction of the charge transfer electrode in size.

Further, in the charge transfer electrode serving as the read electrode, too, it becomes possible to solve the problem in which the read voltage is increased.

According to the present invention, since the sidewall insulating layers are formed on the side surfaces of at least the read electrode of the charge transfer electrodes of a plurality of layers, when then interlayer insulators are formed on the read electrode, it is possible to suppress the electrode from being reduced in size due to the oxidation by suppressing the oxidation of the read electrode.

In consequence, it is possible to solve the problem of the propagation delay in the read electrode by suppressing the resistance from being increased due to the reduction of the read electrode in size. At the same time, it is possible to suppress the read voltage necessary for reading the charges produced when the read electrode is reduced in size and separated from the semiconductor substrate from being increased.

Therefore, according to the present invention, since it is possible to solve the above-mentioned respective problems remarkably caused as the solid-state image pickup device is microminiaturized, the solid-state image pickup device can be microminiaturized, the number of the pixels of the solid-state image pickup device can be increased and the solid-state image pickup device can be increased in density. Furthermore, it becomes possible to make the solid-state image pickup device compact in size.

### BRIEF DESCRIPTION OF THE DRAWINGS

FIG. 1 is a schematic diagram (schematic plan view of a main portion) of an example of a CCD solid-state image pickup device according to the related art;

FIG. 2 is a schematic diagram (schematic plan view of a main portion) of a solid-state image pickup device according to an embodiment of the present invention;

FIG. 3A is a cross-sectional view taken along the line IIIA-IIIA′ of the solid-state image pickup device shown in FIG. 2;

FIG. 3B is a cross-sectional view taken along the line IIIB-IIIB′ of the solid-state image pickup device shown in FIG. 2;

FIG. 3C is a cross-sectional view taken along the line IIIC-IIIC′ of the solid-state image pickup device shown in FIG. 2;

FIGS. 4A to 4C are schematic cross-sectional views showing the manufacturing processes of the solid-state image pickup device shown in FIG. 2, respectively;

FIGS. 5A to 5C are schematic cross-sectional views showing the manufacturing processes of the solid-state image pickup device-shown in FIG. 2, respectively;

FIGS. 6A to 6C are schematic cross-sectional views showing the manufacturing processes of the solid-state image pickup device shown in FIG. 2, respectively;

FIGS. 7A to 7C are schematic cross-sectional views showing the manufacturing processes of the solid-state image pickup device shown in FIG. 2, respectively;

FIGS. 8A to 8C are schematic cross-sectional views showing the manufacturing processes of the solid-state image pickup device shown in FIG. 2, respectively;

FIGS. 9A to 9C are schematic cross-sectional views showing the manufacturing processes of the solid-state image pickup device shown in FIG. 2, respectively;

FIG. 10A is a schematic cross-sectional view taken along the line XA to XA′ of the solid-state image pickup device shown in FIG. 1;

FIG. 10B is a schematic cross-sectional view taken along the line XB-XB′ of the solid-state image pickup device shown in FIG. 1; and

FIG. 10C is a schematic cross-sectional view taken along the line XC-XC′ of the solid-state image pickup device shown in FIG. 1.

### DESCRIPTION OF THE PREFERRED EMBODIMENTS

The present invention will be described with reference to the drawings.

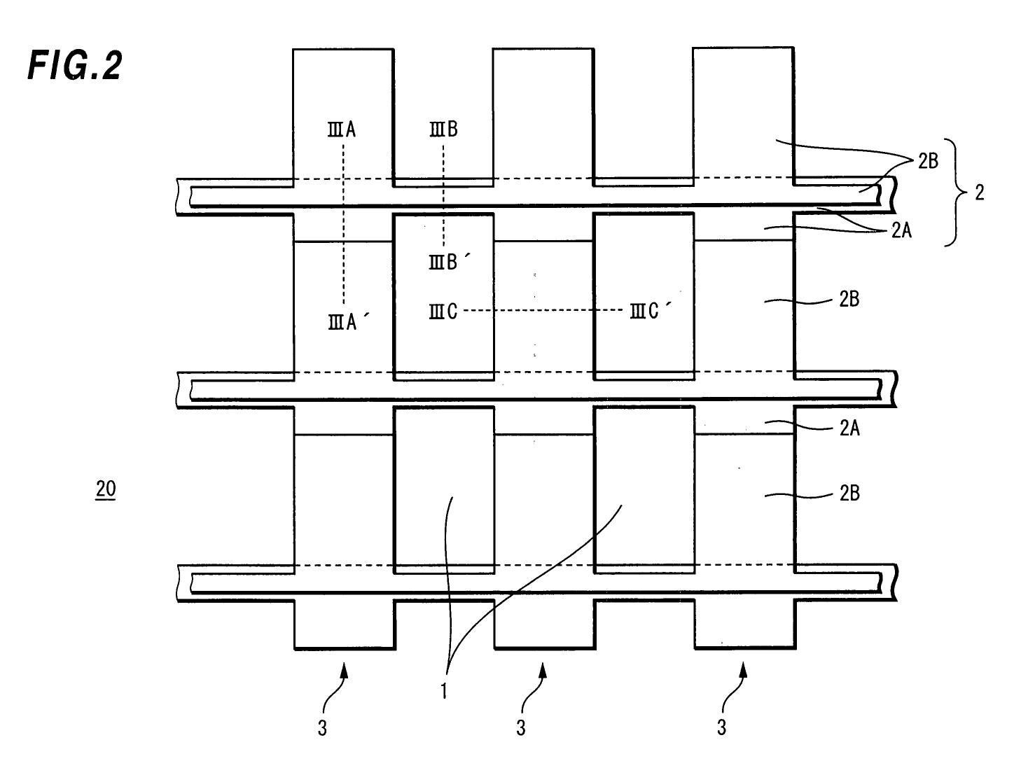

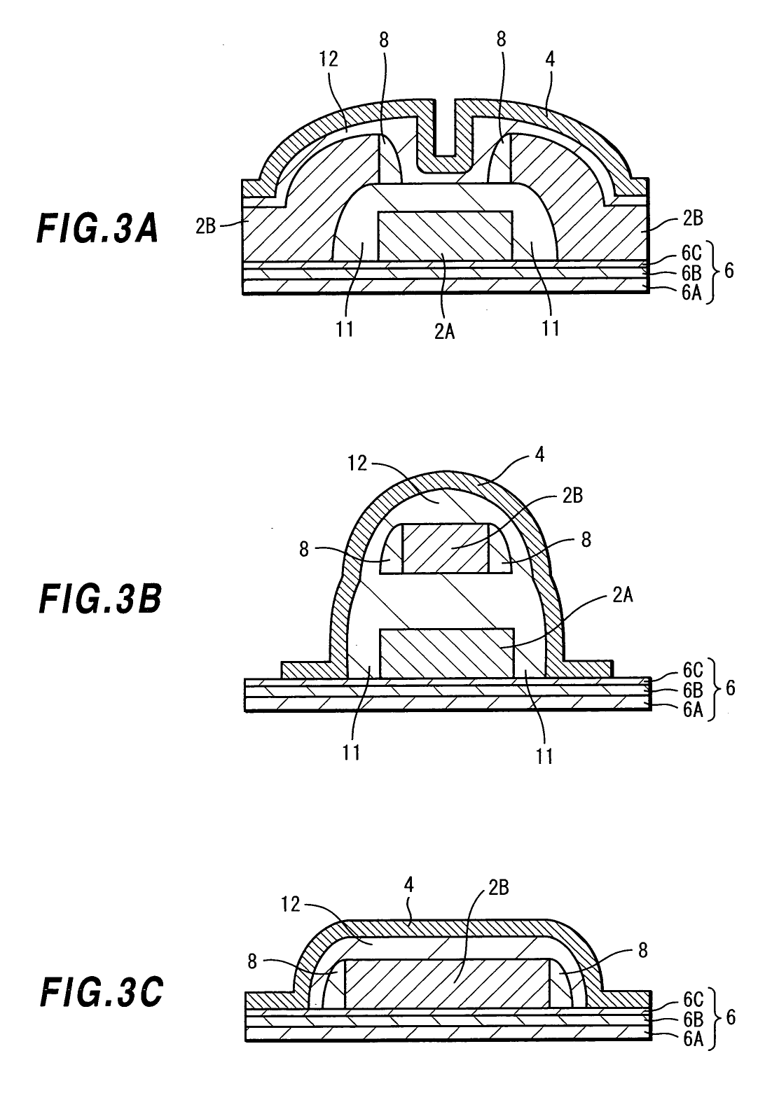

FIG. 2 and FIGS. 3A to 3C are schematic diagrams showing an arrangement of a solid-state image pickup device according to an embodiment of the present invention. FIG. 2 is a plan view showing a main portion (that is, image pickup area) of the solid-state image pickup device according to the present invention in an enlarged scale). FIG. 3A is a cross-sectional view taken along the line IIIA-IIIA′ in FIG. 2; FIG. 3B is a cross-sectional view taken along the line IIIB-IIIB′ in FIG. 2; and FIG. 3C is a cross-sectional view taken along the line IIIC-IIIC′ in FIG. 2.

In this embodiment, the present invention is applied to a CCD solid-state image pickup device.

A solid-state image pickup device, generally depicted by the reference numeral 20 in FIG. 2, comprises light-receiving sensor portions 1 arrayed in a matrix fashion (that is, two-dimensional fashion) and vertical transfer registers 3 formed on one side of respective columns of the light-receiving sensor portions 1 to thereby construct the image pickup area.

Outside of the image pickup area, a horizontal transfer register is connected to one end of the vertical transfer register 3 and an output portion is provided at one end of the horizontal transfer register, although not shown.

The vertical transfer register 3 is composed of a charge transfer electrode 2, a gate insulating film 6 and a transfer channel area, not shown.

The charge transfer electrode 2 is composed of two electrode layers of a charge transfer electrode 2A of a first layer and a charge-transfer-electrode 2B of a second layer.

As shown in FIGS. 3A to 3C, the gate insulating film 6 has a tri-layer laminated structure comprising a silicon oxide film 6A/silicon nitride film 6B/silicon oxide film 6c, that is, ONO structure.

A light-shielding film 4 is formed on the charge transfer electrode 2 through an interlayer insulator 12, and this light-shielding film 4 has an opening (not shown) formed on the light-receiving sensor portion 1.

Above the light-shielding film 4, there are provided a planarized film, a color filter, an on-chip microlens and the like if necessary.

The charge transfer electrode 2A of the first layer and the charge transfer electrode 2B of the second layer can be formed of a conductive film such as a polysilicon film, a tungsten silicide film or a film made of both of tungsten, tungsten nitride or a polysilicon film and a metal film (laminated film or alloy film).

The light-shielding film 4 can be formed of a material with high reflectance such as titanium (Ti), tungsten silicide (WSI) tungsten (W), aluminum (Al) or alloy thereof.

In the solid-state image pickup device 20 according to this embodiment, in particular, sidewall insulating layers are respectively formed on the side surfaces of the charge transfer electrodes 2A, 2B of the two layers of the charge transfer electrode 2 of the vertical transfer register 3. More specifically, a sidewall insulating layer 11 is formed on the side surface of the charge transfer electrode 2A of the first layer, and a sidewall insulating layer 8 is formed on the sidewall of the charge transfer electrode 2B of the second layer.

These sidewall insulating layers 11, 8 are made of a suitable film such as an oxide film or a nitride film.

Since the sidewall insulating layers 11, 8 are formed on the side surfaces of the charge transfer electrodes 2A, 2B, in the process for forming the interlayer insulator over the charge transfer electrodes 2A, 2B, the sidewall insulating layers 11, 8 make the charge transfer electrodes 2A, 2B become difficult to oxidized, and hence it is possible to suppress the charge transfer electrodes 2A, 2B from being reduced in size due to the direct oxidation of the charge transfer electrodes 2A, 2B.

The solid-state image pickup device 20 according to this embodiment can be manufactured by the following processes, for example.

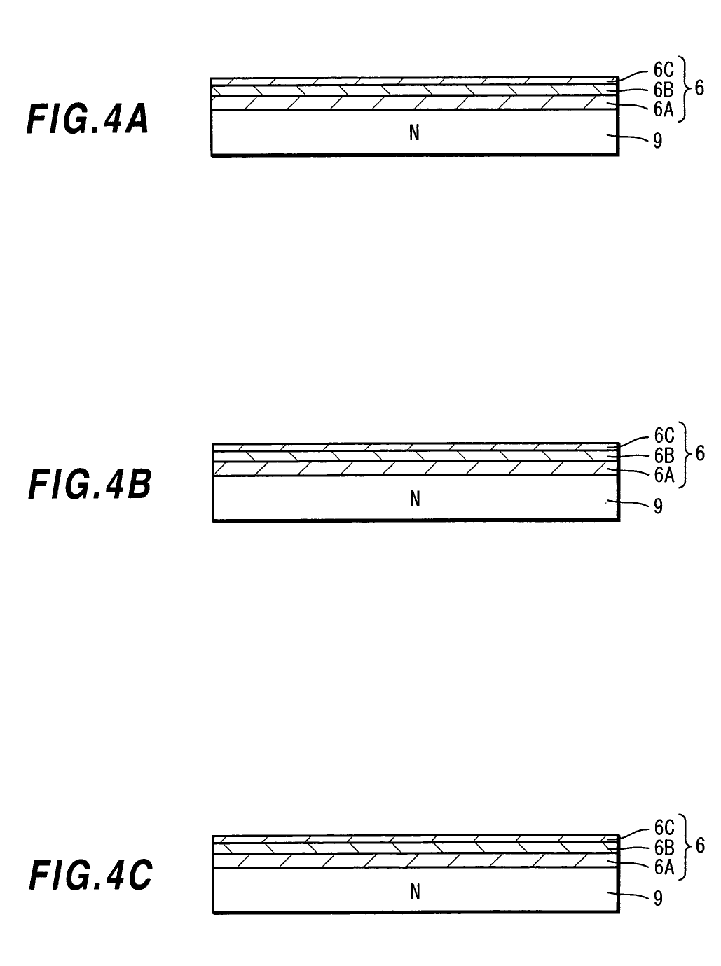

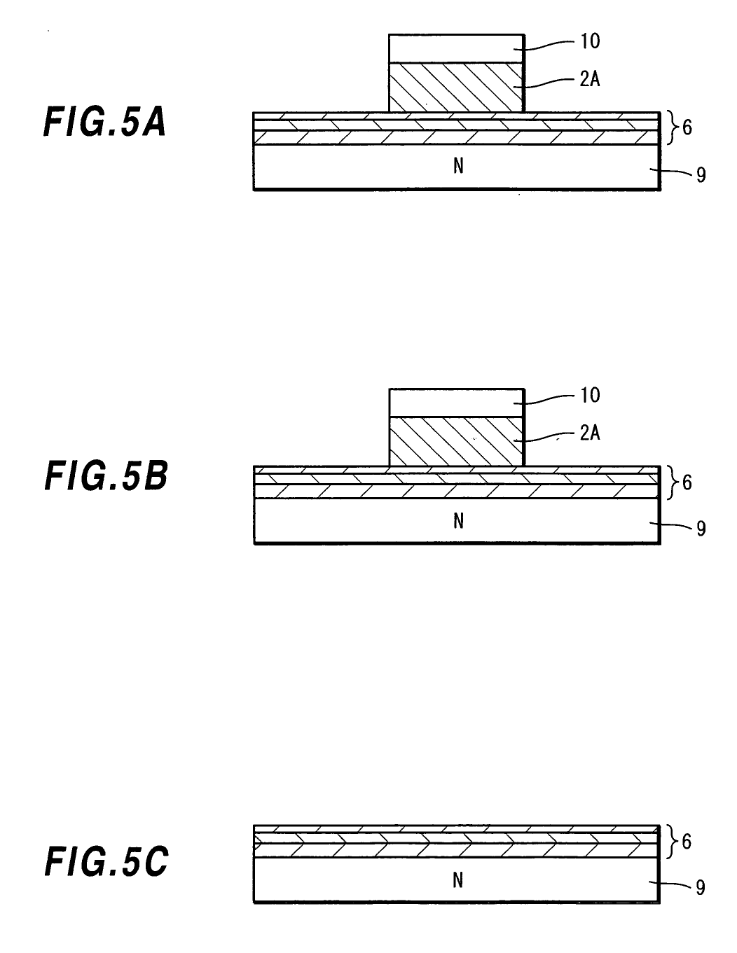

In FIGS. 4A to 4C and FIGS. 9A to 9C, FIGS. 4A to 9A are cross-sectional views showing the solid-state image pickup device from the same surface as that of FIG. 3A, FIGS. 4B to 9B are cross-sectional views showing the solid-state image pickup device from the same surface as that of FIG. 3B, and FIGS. 4C to 9C are cross-sectional views showing the solid-state image pickup device from the same surface as that of FIG. 3C.

First, as shown in FIGS. 4A to 4C, a silicon oxide film 6A, a silicon nitride film 6B and a silicon oxide film 6C are deposited on an n-type semiconductor substrate 9; for example, in that order, to form a gate insulating film 6 having a so-called ONO structure in which these films 6A, 6B, 6C are laminated.

After that, a conductive film used to form the charge transfer electrode 2A of the first layer is deposited on the gate insulating film 6 and an oxide film that serves as an offset oxide film is deposited on the resultant conductive film. These conductive film and oxide film can be deposited by vapor-phase growth.

Further, these conductive film and oxide film are processed by a dry-etching method while a photoresist, not shown, is being used as a mask, whereby the charge transfer electrode 2A of the first layer and the offset oxide film 10 on the charge transfer electrode 2A can be formed with predetermined patterns.

Next, the interlayer insulator is deposited between the charge transfer electrode 2A of the first layer and the charge transfer electrode 2B of the second layer.

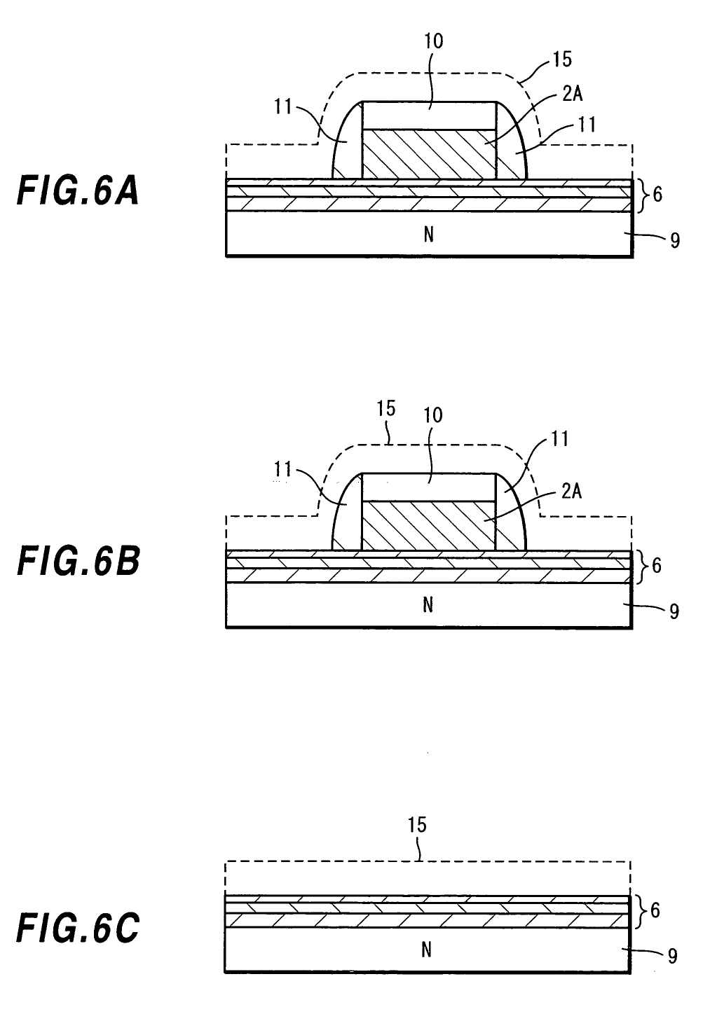

More specifically, as shown by broken lines in FIGS. 6A to 6C, an insulating layer (for example, oxide film or nitride film) 15 is deposited on the surface by vapor-phase growth, for example. Then, a sidewall insulating layer 11 is deposited on the side surface of the charge transfer electrode 2A of the first layer by effecting etch-back process on the whole surface as shown in FIGS. 6A to 6C.

Next, the offset oxide film 10 and the sidewall insulating layer 11 constitute the interlayer insulator between the charge transfer electrode 2A of the first layer and the charge transfer electrode 2B of the second layer.

This interlayer insulator can be formed by a method in which the offset oxide film 10 is not formed but the electrode is directly oxidized or a method using both of the sidewall insulating layer and the oxidation.

Since the sidewall insulating layers 11 are formed on the side surface of the charge transfer electrode 2A of the first layer, when the interlayer insulator is formed by directly oxidizing the electrode, the side surfaces of the charge transfer electrodes 2A become difficult to oxidized, and hence it is possible to suppress the charge transfer electrode 2A from being reduced in size due to direct oxidation of the charge transfer electrode 2A.

A boundary between the offset oxide film 10 and the sidewall insulating layer 11 is not shown in the following sheets of drawings.

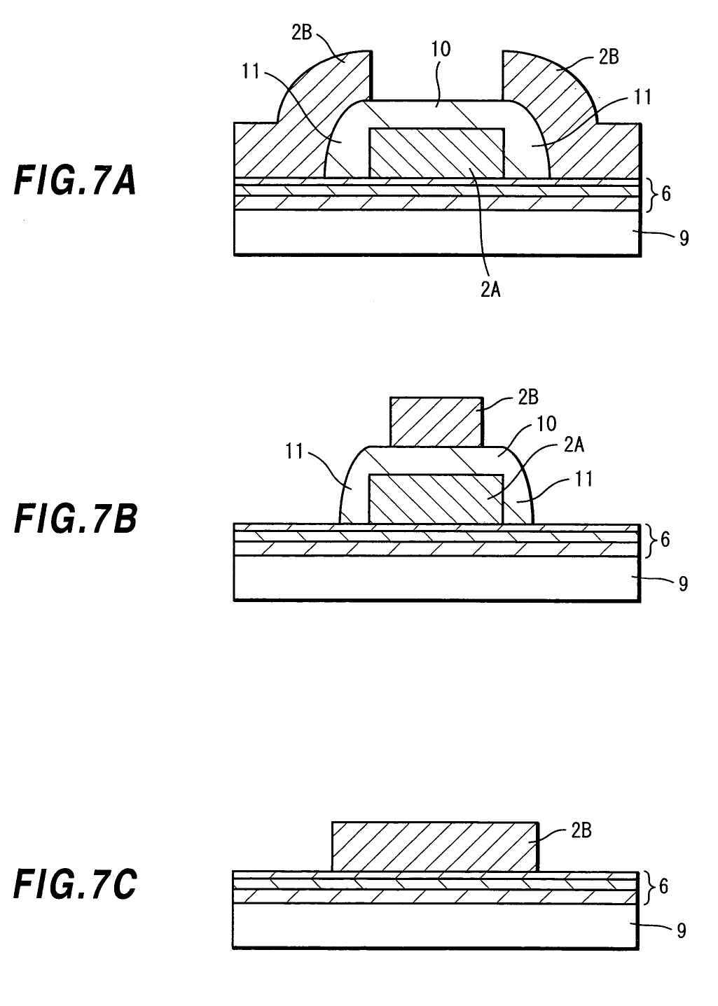

Next, a conductive film used to form the charge transfer electrode 2B of the second layer is deposited and the conductive film is processed by a dry etching method while a photoresist, not shown, is being used as a mask, whereby the charge transfer electrode 2B of the second layer is formed with a predetermined pattern as shown in FIGS. 7A to 7C.

As a consequence, in the cross-section along the charge transfer direction of the vertical transfer register 3 shown in FIG. 7A, the charge transfer electrode 2B of the second layer is formed from the gate insulating film 6 across the upper side of the charge transfer electrode 2A of the first layer. In the cross-section between the pixels of the light-receiving sensor portion 2 shown in FIG. 7B, the charge transfer electrode 2B of the second layer is formed on the offset oxide film 10 above the charge transfer electrode 2A of the first layer. Also, in the cross-section of the charge reading direction of the vertical transfer register 3 shown in FIG. 7C, the charge transfer electrode 2B of the second layer is formed on the gate insulating film 6.

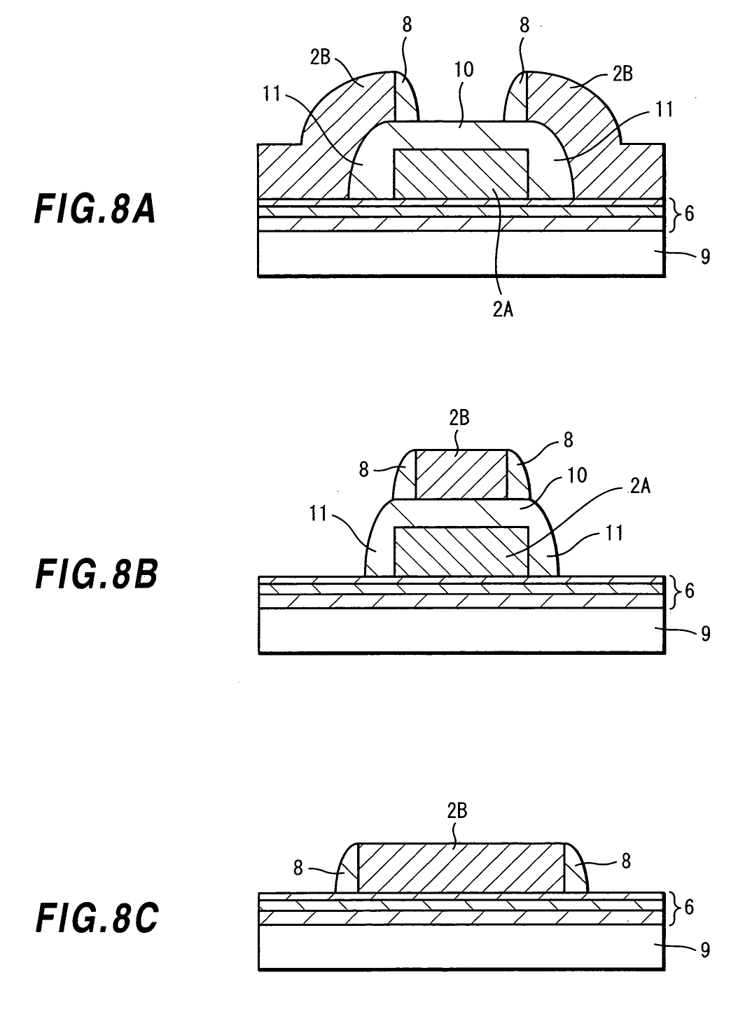

Next, an insulating layer (for example, oxide film or nitride film) is deposited on the surface and the whole surface is treated by the etch-back process, whereby sidewall insulating layers 8 formed of oxide films or nitride films are formed on the side surfaces of the charge transfer electrodes 2B of the second layer as shown in FIGS. 8A to 8C.

Subsequently, an interlayer insulator 12 is formed over the surface so as to cover the charge transfer electrode 2B of the second layer.

As a method for forming this interlayer insulator 12, there may be considered a method for oxidizing the charge transfer electrode 2B of the second layer after the sidewall insulating layers 8 were formed, a method for forming the oxide film by vapor-phase growth or a method using both of the oxidation of the charge transfer electrode 2B and the vapor-phase growth of the oxide film.

At that time, since the sidewall insulating layers 8 are formed on the side surfaces of the charge transfer electrode 2B of the second layer, the side surfaces of the charge transfer electrode 2B of the second layer become difficult to be oxidized and hence the charge transfer electrode 2B can be suppressed from being reduced in size due to the oxidation of the sidewalls.

The interlayer insulator 12 is removed at its portion that covers the charge transfer electrodes 2A, 2B, that is, at its portion near the light-receiving sensor portion 1, whereby the light-shielding film 4 can be formed at the lower position.

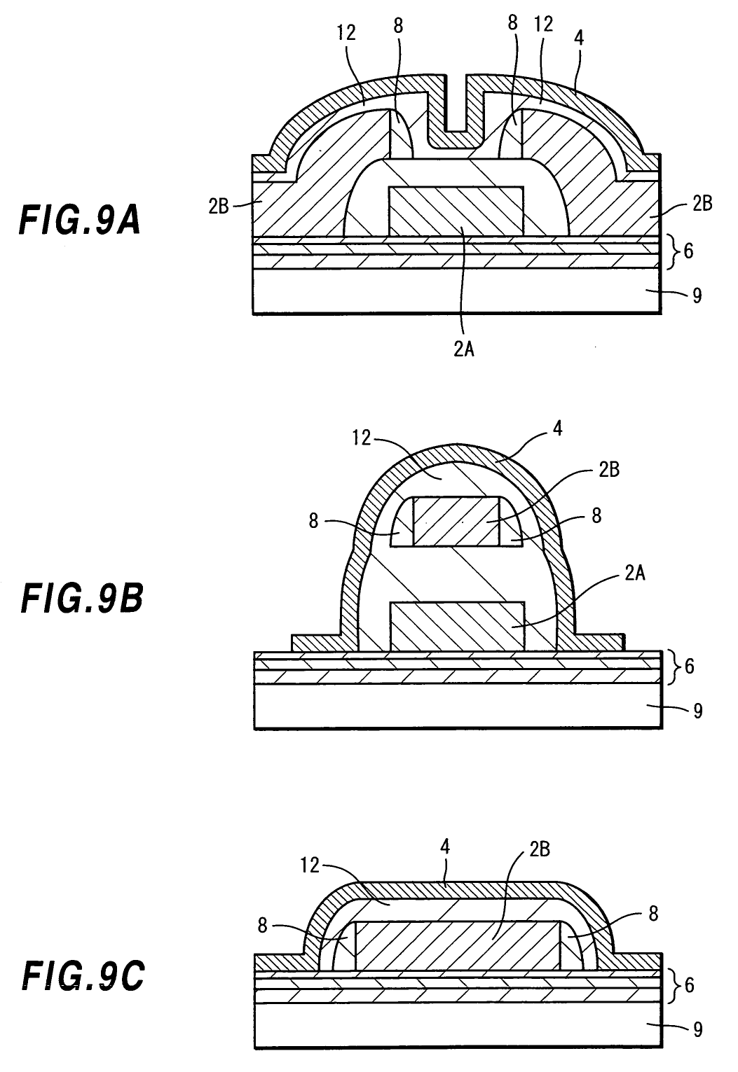

Next, as shown in FIGS. 9A to 9C, the light-shielding film 4 is deposited on the interlayer insulator 12.

After the film that serves as the light-shielding film 4 was deposited on the whole surface, the light-shielding film 4 with the predetermined pattern is formed by processing the resultant film according to a dry etching method while a photoresist is being used as a mask.

With respect to each portion of the layer over the light-shielding film 4 can be formed similarly according to a conventional technique.

More specifically, after the manufacturing processes shown in FIGS. 4A to 4C and FIGS. 9A to 9C, a microlens or a color filter, not shown, can be formed by the processes similar to those of the related art.

Also, a transfer channel area of the vertical transfer register 3, a photodiode of the light-receiving sensor portion 1 and the like are formed on the semiconductor substrate 9, although not shown.

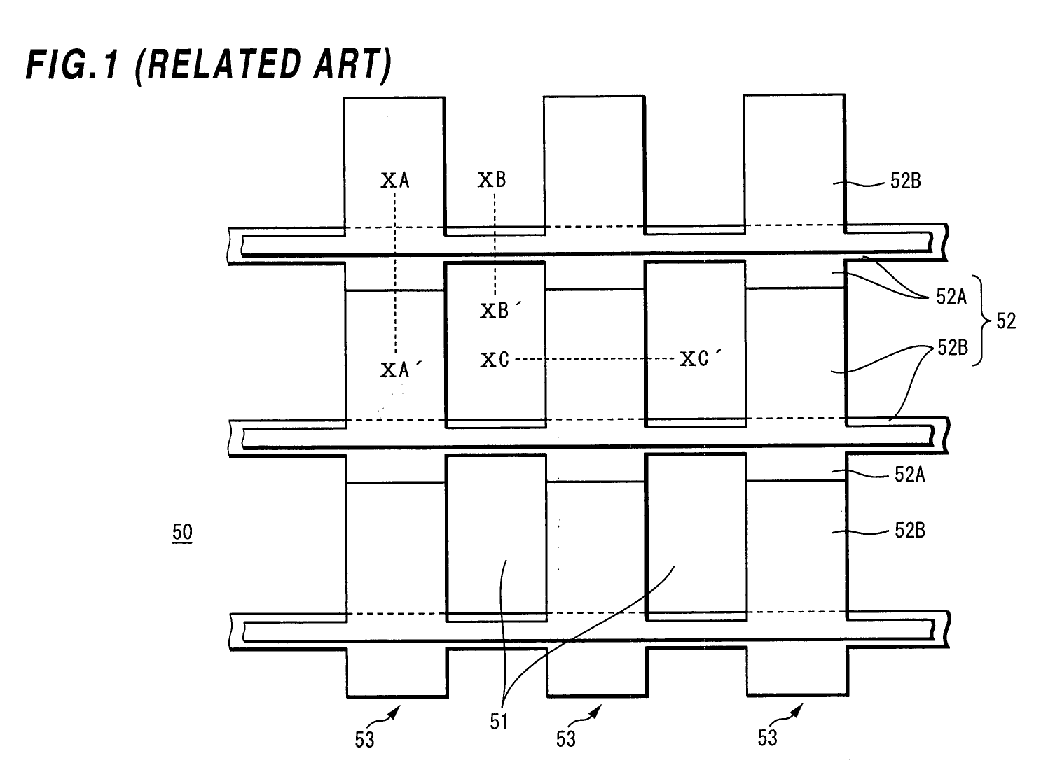

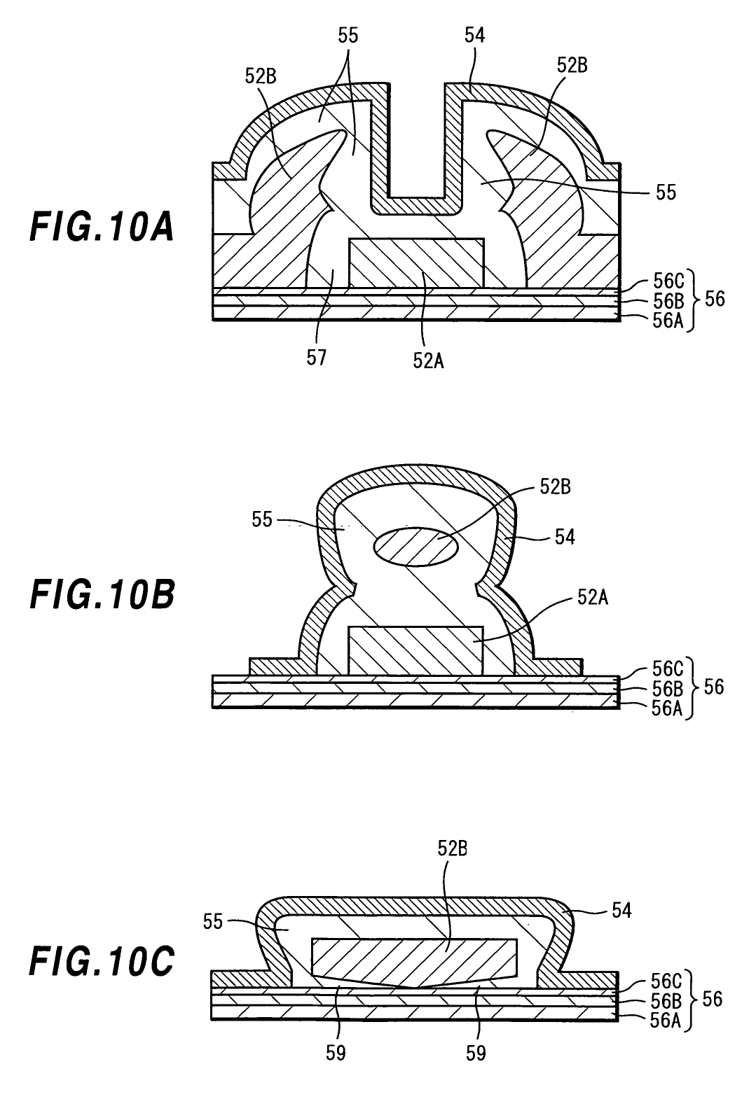

In comparison with and in contrast with the present invention, with respect to the arrangement of the CCD solid-state image pickup device 50 which is shown in the plan view of FIG. 1, problems which arise when the solid-state image pickup device is more microminiaturized will be described with reference to FIGS. 10A to 10C. FIG. 10A is a cross-sectional view taken along the line XA to XA′ in FIG. 1; FIG. 10B is a cross-sectional view taken along the line XB to XB′ in FIG. 1; and FIG. 10C is a cross-sectional view taken along the line XC to XC′ in FIG. 1.

In the process for forming the interlayer insulator that insulates the charge transfer electrode 52B of the second layer and the light-shielding film, the portion near the surface of the charge transfer electrode 52B of the second layer is oxidized by the above-mentioned direct oxidation of the electrode.

Then, although the size of the charge transfer electrode is also reduced as microminiaturization of the CCD solid-state image pickup device 50 advances, since the thickness of the portion to be oxidized is not changed so much, a ratio of the oxidized portion increases and hence a ratio in which the electrode is reduced by the oxidation becomes remarkable.

Accordingly, as shown in FIGS. 10A and 10B, the charge transfer electrode 52B of the second layer is reduced in thickness by the oxidation and hence a low sheet resistance cannot be obtained. Since the low sheet resistance cannot be obtained as described above, a problem arises, in which charge transfer efficiency is deteriorated by propagation delay.

Also, as shown in FIG. 10A, since the charge transfer electrode 52B of the second layer is separated from the charge transfer electrode 52A of the first layer, a desired electric field cannot be applied to a gap portion 57 between the charge transfer electrode 52A of the first layer and the charge transfer electrode 52B of the second layer, which causes charge transfer efficiency to be deteriorated.

Also, as shown in FIG. 10C, an oxidized portion 59 is formed between the charge transfer electrode 52B of the second layer and the gate insulating film 56 (56A, 56B, 56C) so that the charge transfer electrode 52B of the second layer is separated from the gate insulating film 56. In the portion of which cross-section is shown in FIG. 10C, the charge transfer electrode 52B of the second layer serves as a read electrode for reading signal charges (electrons) photoelectrically-converted by the light-receiving sensor portion 51 to the gate insulating film 56, too. Thus, when the charge transfer electrode 52B is separated from the gate insulating film 56, a distance between the semiconductor region beneath the gate insulating film 56 and the charge transfer electrode 52B increases, and a problem arises, in which a read voltage necessary for reading the signal charges to the vertical transfer register 53 rises.

On the other hand, in the solid-state image pickup device 20 according to this embodiment, since the sidewall insulating layers 11 make the side surfaces of the charge transfer electrode 2A of the first layer become difficult to be oxidized and the sidewall insulating layers 8 make the side surfaces of the charge transfer electrode 2B of the second layer become difficult to be oxidized, it is possible to suppress the electrode from being reduced in size due to the oxidations of the charge transfer electrode 2A of the first layer and the charge transfer electrode 2B of the second layer.

As a result, as shown in FIG. 3A, since the charge transfer electrode 2B of the second layer can be prevented from being separated from the charge transfer electrode 2B of the first layer, a desired electric field can be applied to the gap portion between the charge transfer electrode 2A of the first layer and the charge transfer electrode 2B of the second layer and hence satisfactory charge transfer efficiency can be maintained.

Also, as shown in FIGS. 3A to 3C, the charge transfer electrode 2A of the first layer and the charge transfer electrode 2B of the second layer can be formed with sufficient thicknesses and sizes and the low sheet resistance can be obtained. Hence, it is possible to solve the problem in which the charge transfer efficiency is deteriorated by propagation delay.

Further, as shown in FIG. 3C, the charge transfer electrode 2B of the second layer serving as the read electrode can be formed in close contact with the gate insulating film 6 and hence it is possible to solve the problem in which the read voltage is raised.

According to the arrangement of the above-mentioned solid-state image pickup device 20 according to this embodiment, the sidewall insulating layers 11, 8 are formed on the side surfaces of the charge transfer electrodes 2A, 2B of the two layers of the charge transfer electrodes 2 (2A, 2B), respectively. As a result, in the process for forming the interlayer insulators on the charge transfer electrodes 2A, 2B of the respective layers when the solid-state image pickup device 20 is manufactured, it becomes possible to make the side surfaces of the charge transfer electrodes 2A, 2B become difficult to be oxidized by the sidewall insulating layers 11, 8 formed on the side surfaces.

Also, in the above-mentioned manufacturing processes, after the charge transfer electrode 2A of the first layer was formed, the oxide film or the nitride film is deposited on the whole surface and the sidewall insulating layers 11 are formed on the side surfaces of the charge transfer electrode 2A of the first layer by effecting the etch-back process on this oxide film or the nitride film. Also, after the charge transfer electrode 2B of the second layer was formed, the oxide film or the nitride film is deposited on the whole surface and the sidewall insulating layers 8 are formed on the side surfaces of the charge transfer electrode 2B of the second layer by etch-backing this oxide film or the nitride film. Thus, it becomes possible to make the side surfaces of the charge transfer electrodes 2A, 2b difficult to be oxidized by the sidewall insulating layers 11, 8 formed on the side surfaces. As a result, when the interlayer insulators are formed on the charge transfer electrodes 2A, 2B of the respective layers, it is possible to suppress the charge transfer electrodes 2A, 2B from being reduced in size due to the oxidations of the electrodes.

Accordingly, since the charge transfer electrodes 2A, 2B can be suppressed from being reduced in size due to the oxidations of the electrodes and the resistance can be suppressed from being increased due to the reduction of the electrodes in size, it is possible to solve the problem of the propagation delay of the charge transfer electrodes 2 (2A, 2B). Also, since the gap portion can be suppressed from being enlarged at the overlapping portion of the charge transfer electrodes 2A, 2B due to the reduction of the charge transfer electrod3e 2B of the second layer, it is possible to solve the problem in which the charge transfer efficiency in the charge transfer electrodes 2A, 2B is deteriorated.

Further, in the charge transfer electrode 2B of the second layer serving as the read gate electrode, since it is possible to suppress the charge transfer electrode 2B from being separated from the gate insulating film 6 (the charge transfer electrode 2B can be suppressed from being turned up) due to the oxidation of the charge transfer electrode 2B of the second layer, while the insulating layer between the charge transfer electrode 2B of the second layer and the substrate is being kept to be thin, it becomes possible to suppress the read voltage necessary for reading signal charges from being increased.

Therefore, according to the present invention, since the above-mentioned respective problems which arise remarkably as the solid-state image pickup device is microminiaturized can be solved, it becomes possible to microminiaturize the solid-state image pickup device, the number of the pixels of the solid-state image pickup device can be increased and the solid-state image pickup device can be increased in density.

Also, since the solid-state image pickup device can be microminiaturized, the area per the same number of pixels can be decreased and hence the solid-state image pickup device can be made compact in size.

While the charge transfer electrode 2 of the vertical transfer register 3 is composed of the electrode layers 2A, 2B of the two layers and signal charges are transferred in the vertical transfer register 3 in a two-phase driving fashion in the above-mentioned embodiment, the present invention can be applied to other arrangements.

When the charge transfer electrode is composed of electrode layers of more than three layers, the sidewall insulating layers may be formed not only in the charge transfer electrodes of the first and second layers but on the charge transfer electrodes of the layers following the third layer.

Also in the arrangement in which signal charges are transferred in the vertical transfer electrode in a three-phase driving fashion or a four-phase driving fashion, the sidewall insulating layers may be formed on the side surfaces of the charge transfer electrodes of the respective layers.

Furthermore, while the sidewall insulating layers are formed on both of the charge transfer electrodes 2A, 2B of the two layers in the above-mentioned embodiment, by forming the sidewall insulating layers on the charge transfer electrode serving as the read electrode to which at least the read voltage, for example, is applied (the charge transfer electrode 2B of the second layer in the solid-state image pickup device 20 shown in FIG. 2), there can be achieved the effect in which the rise of the read voltage can be suppressed.

According to the present invention, since the sidewall insulating layers are formed in the side surfaces of the charge transfer electrodes of the respective layers, when the interlayer insulators are formed on the charge transfer electrodes, it is possible to suppress the electrodes from being reduced in size due to the oxidation by suppressing the oxidation of the charge transfer electrodes.

Thus, by suppressing the resistance from being increased as the charge transfer electrodes are reduced in size, it is possible to solve the problem of the propagation delay in the charge transfer electrode. Also, it is possible to solve the problem in which the charge transfer efficiency is deteriorated by the reduction of the charge transfer electrode.

Further, in the charge transfer electrode serving as the read electrode, too, it becomes possible to solve the problem in which the read voltage is increased.

According to the present invention, since the sidewall insulating layers are formed on the side surfaces of at least the read electrode of the charge transfer electrodes of a plurality of layers, when then interlayer insulators are formed on the read electrode, it is possible to suppress the electrode from being reduced in size due to the oxidation by suppressing the oxidation of the read electrode.

In consequence, it is possible to solve the problem of the propagation delay in the read electrode by suppressing the resistance from being increased due to the reduction of the read electrode in size. At the same time, it is possible to suppress the read voltage necessary for reading the charges produced when the read electrode is reduced in size and separated from the semiconductor substrate from being increased.

Therefore, according to the present invention, since it is possible to solve the above-mentioned respective problems remarkably caused as the solid-state image pickup device is microminiaturized progressively, the solid-state image pickup device can be microminiaturized, the number of the pixels of the solid-state image pickup device can be increased and the solid-state image pickup device can be increased in density. Furthermore, it becomes possible to make the solid-state image pickup device compact in size.

Having described preferred embodiments of the invention with reference to the accompanying drawings, it is to be understood that the invention is not limited to that precise embodiment and that various changes and modifications could be effected therein by one skilled in the art without departing from the spirit or scope of the invention as defined in the appended claims.

1. A solid-state image pickup device comprising:
a light-receiving sensor portion;
a charge transfer portion provided on one side of said light-receiving portion;
a plurality layers of charge transfer electrodes comprising said charge transfer portion; and
sidewall insulating layers formed on side surfaces of said charge transfer electrodes of respective layers of said plurality of charge transfer electrodes.

2. A solid-state image pickup device manufacturing method for forming a solid-state image pickup device in which a charge transfer portion is provided on one side of a light-receiving sensor portion, said charge transfer portion being composed of charge transfer electrodes of a plurality of layers, comprising:
the process for forming charge transfer electrodes; and
the process for forming an insulating film on the whole surface and for forming sidewall insulating layers on side surfaces of charge transfer electrodes of respective layers of the charge transfer electrodes of said plurality of layers by effecting etch-back process on said insulating film.

3. A solid-state image pickup device comprising:
a light-receiving sensor portion;
a charge transfer portion provided on one side of said light-receiving portion;
a plurality layers of charge transfer electrodes comprising said charge transfer portion; and
sidewall insulating layers formed on side surfaces of at least a read electrode of said charge transfer electrodes of said plurality of charge transfer electrodes.

4. A solid-state image pickup device manufacturing method for forming a solid-state image pickup device in which a charge transfer portion is provided on one side of a light-receiving sensor portion, said charge transfer portion being composed of charge transfer electrodes of a plurality of layers, comprising:
the process for forming charge transfer electrodes; and
the process for forming an insulating film on the whole surface and for forming sidewall insulating layers on side surfaces of at least a read electrode of the charge transfer electrodes of said plurality of layers by effecting etch-back process on said insulating film.
